(19) United States
(12) Patent Application Publication
(10) Pub. No.: US 2008/0169086 A1
(43) Pub. Date: Jul. 17, 2008

(54) Heat dissipating device

(75) Inventors: Jen-Lu Hu, Tainan City (TW); Hao-Hui Lin, Taitung City (TW); Tsung-Ching Sun, Tainan City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Man Zai Industrial Co., Ltd., Tainan City (TW)

(21) Appl. No.: 11/652,894

(22) Filed: Jan. 11, 2007

(51) Int. Cl. H05K 7/20

(52) U.S. Cl. 165/80.4; 165/104.33; 361/699

(57) ABSTRACT

A heat dissipating device is adapted to be connected to a heat sink and includes: a radiator including first and second side tanks adapted to store a coolant therein, a fin structure disposed between and interconnecting the first and second side tanks, and connecting conduits connected to the fin structure and interconnecting and in fluid communication with the first and second side tanks, the radiator further including a buffer tank that is mounted on and that is in fluid communication with the first side tank and that has a coolant outlet adapted to be connected to the heat sink, the second side tank having a coolant inlet adapted to be connected to the heat sink; and a pump mounted directly on the buffer tank.

### BACKGROUND OF THE INVENTION

1. Field of the Invention

The invention relates to a heat dissipating device, more particularly to a heat dissipating device having a side tank and a pump mounted on the side tank.

2. Description of the Related Art

As shown in FIG. 1, a conventional heat dissipating device, adapted to be connected to inlet and outlet 21, 22 of a heat sink 2 which is in contact with a heat source, such as a CPU or a heat-generating component of a display, generally includes a radiator 11, an inlet conduit 12, an outlet conduit 13, and a pump 14. The radiator 11 includes a first side tank 111, a second side tank 112, and a connecting conduit assembly 113 interconnecting the first and second side tanks 111, 112. The inlet conduit 12 interconnects the first side tank 111 and the coolant inlet 21 of the heat sink 2. The outlet conduit 13 interconnects the second side tank 112 and the coolant outlet 22 of the heat sink 2. The pump 14 is mounted on the inlet conduit 12 such that the inlet conduit 12 has a first conduit section 121 interconnecting the first side tank 111 and the pump 14, and a second conduit section 122 interconnecting the pump 4 and the heat sink 2.

When the pump 14 is operated, a coolant in the first side tank 111 flows through the first conduit section 121, the second conduit section 122, and enters the heat sink 2 through the coolant inlet 21. After conducting heat exchange to absorb heat from the heat sink 2, the high-temperature coolant flows through the outlet conduit 13 into the second side tank 112 and then through the connecting conduits 113 into the first side tank 111 to complete a circulation cycle.

Although the conventional heat dissipating device has the heat dissipating effect, there are still some disadvantages:

1) An undesired high coolant vaporizing rate due to connection between the pump 14 and the first and second conduit sections 121, 122 of the inlet conduit 12 occurs.

2) A larger space is required to accommodate the pump 14 and the first and second conduit sections 121, 122 of the inlet conduit 12.

3) Assembly of the pump 14 and the first and second conduit sections 121, 122 of the inlet conduit 12 is inconvenient when the space for accommodating the heat dissipating device is small.

### SUMMARY OF THE INVENTION

Therefore, the object of the present invention is to provide a heat dissipating device that can overcome the aforesaid disadvantages associated with the prior art.

According to one aspect of the present invention, there is provided a heat dissipating device adapted to be connected to a heat sink and comprising: a radiator including first and second side tanks adapted to store a coolant therein, a fin structure disposed between and interconnecting the first and second side tanks, and a plurality of connecting conduits connected to the fin structure and interconnecting and in fluid communication with the first and second side tanks, the first side tank having a coolant outlet that is adapted to be connected to the heat sink, the second side tank having a coolant inlet that is adapted to be connected to the heat sink; and a pump mounted directly on the first side tank so as to circulate the coolant through the first side tank, the heat sink, the second side tank, and the connecting conduits.

According to another aspect of the present invention, there is provided a heat dissipating device adapted to be connected to a heat sink and comprising: a radiator including first and second side tanks adapted to store a coolant therein, a fin structure disposed between and interconnecting the first and second side tanks, and a plurality of connecting conduits connected to the fin structure and interconnecting and in fluid communication with the first and second side tanks, the radiator further including a buffer tank that is mounted on and that is in fluid communication with the first side tank and that has a coolant outlet adapted to be connected to the heat sink, the second side tank having a coolant inlet that is adapted to be connected to the heat sink; and a pump mounted directly on the buffer tank so as to circulate the coolant through the buffer tank, the heat sink, the second side tank, the connecting conduits, and the first side tank.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional heat dissipating device;

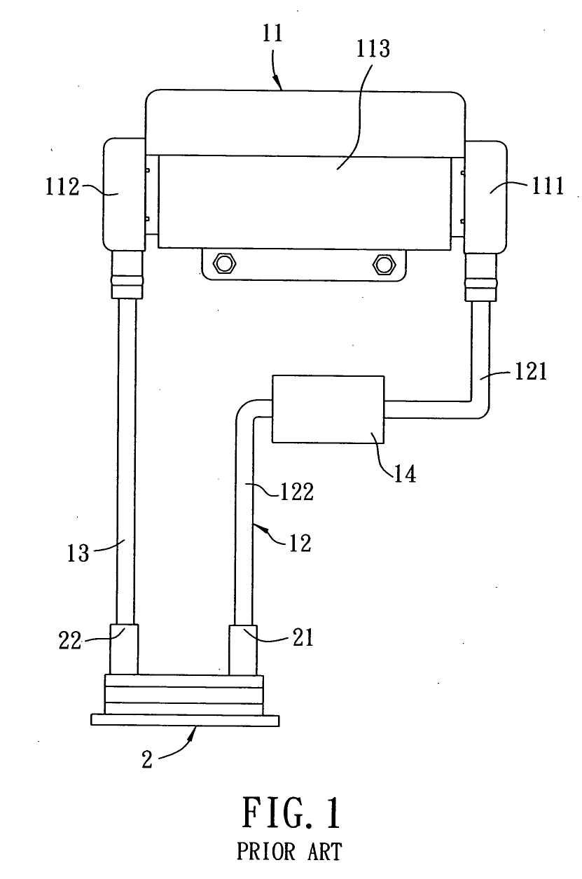

FIG. 2 is a perspective view of the first preferred embodiment of a heat dissipating device according to the present invention;

FIG. 3 is a partly sectional view of a radiator of the first preferred embodiment;

FIG. 4 is a perspective view of the second preferred embodiment of a heat dissipating device according to the present invention;

FIG. 5 is a perspective view of the third preferred embodiment of a heat dissipating device according to the present invention;

FIG. 6 is a partly sectional view of a radiator of the third preferred embodiment; and

FIG. 7 is a perspective view of the fourth preferred embodiment of a heat dissipating device according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

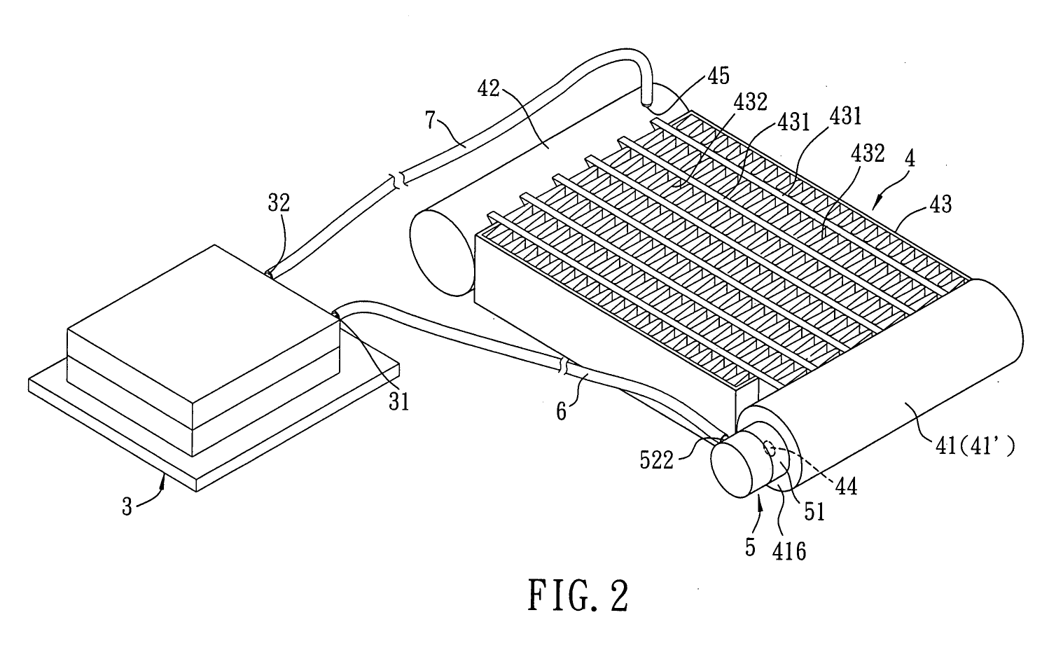

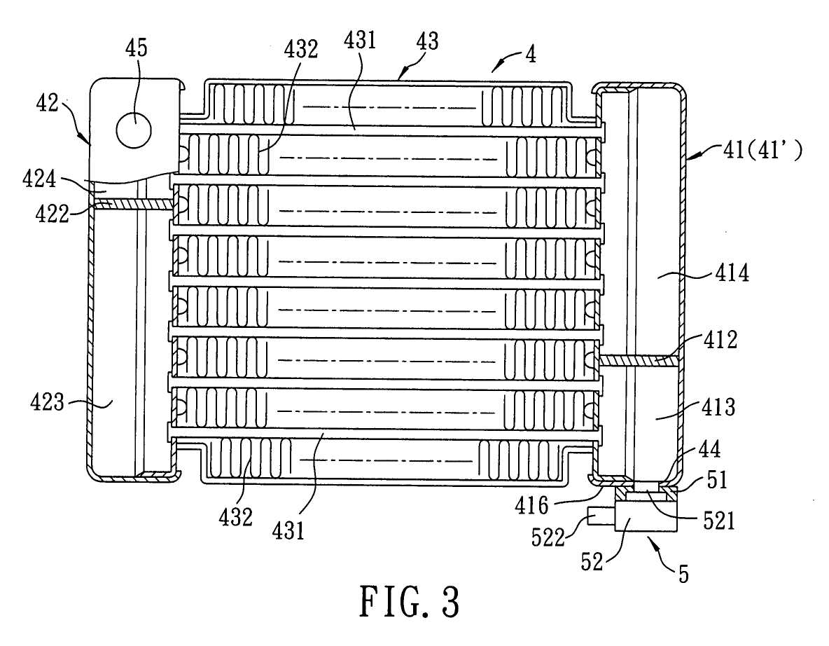

Referring to FIGS. 2 and 3, the first preferred embodiment of a heat dissipating device according to the present invention is shown to be adapted to be connected to a heat sink 3, and comprises: a radiator 4 including first and second side tanks 41, 42 adapted to store a coolant therein, a fin structure 43 disposed between and interconnecting the first and second side tanks 41, 42, and a plurality of connecting conduits 431 connected to fins 432 of the fin structure 43 and interconnecting and in fluid communication with the first and second side tanks 41, 42, the first side tank 41 having a coolant outlet 44 that is adapted to be connected to a sink inlet 31 of the heat sink 3 through an inlet tube 6, the second side tank 42 having a coolant inlet 45 that is adapted to be connected to a sink outlet 32 of the heat sink 3 through an outlet tube 7; and a pump 5 mounted directly on the first side tank 41 so as to circulate the coolant through the first side tank 41, the heat sink 3, the second side tank 42, and the connecting conduits 43.

The radiator 4 and the heat sink 3 are made from a metal material. The heat sink 3 is mounted on an electronic component (not shown), such as a CPU or a heat-generating component of a display.

Referring again to FIG. 2, the first and second side tanks 41, 42 are opposite to each other in a first direction, and the first side tank 41 has a housing 41′ that has a pump-mounting wall 416 facing in a second direction transverse to the first direction. The coolant outlet 44 of the first side tank 41 is formed on the pump-mounting wall 416. The coolant outlet 44 of the first side tank 41 is further provided with a cylindrical coupler 51. The pump 5 has an inlet port 521 that is connected to the coolant outlet 44 of the first side tank 41 through the cylindrical coupler 51, and an outlet port 522 that is connected to the inlet tube 6. It is noted that the cylindrical coupler 51 is optional and can be dispensed with so that the pump 5 is directly mounted on the coolant outlet 44 in other embodiments of the invention.

Referring again to FIG. 3, the first side tank 41 includes a first partition plate 412 that is mounted inside the first side tank 41 so as to partition the first side tank 41 into a first chamber 413 in fluid communication with the coolant outlet 44, and a second chamber 414. The second side tank 42 includes a second partition plate 422 that is mounted inside the second side tank 42 so as to partition the second side tank 42 into a third chamber 423 and a fourth chamber 424 in fluid communication with the coolant inlet 45. The first and third chambers 413, 423 are in fluid communication with each other through respective ones of the connecting conduits 431, the second and third chambers 414, 423 are in fluid communication with each other through respective ones of the connecting conduits 431, whereas the second and fourth chambers 414, 424 are in fluid communication with each other through respective ones of the connecting conduits 431.

Before use, the coolant is filled in the first and second side tanks 41, 42, the connecting conduits 43, the inlet tube 6 and the outlet tube 7. In use, the pump 5 is started, so that the coolant in the first chamber 413 of the first side tank 41 is pumped through the inlet tube 6 into the heat sink 3 for heat exchange with the high-temperature electronic component (not shown). Thereafter, the heated coolant flows in sequence through the outlet tube 7, the fourth chamber 424 of the second side tank 42, the respective connecting conduits 431 interconnecting the second and fourth chambers 414, 424, the second chamber 414 of the first side tank 41, the respective connecting conduits 431 interconnecting the second and third chambers 414, 423, the third chamber 423 of the second side tank 42, the respective connecting conduits 431 interconnecting the first and third chambers 413, 423, and into the first chamber 413 of the first side tank 41. As the coolant flows through the connecting conduits 431, the fin structure 432 absorbs and dissipates heat therefrom so that when the coolant flows into the first chamber 413, the coolant is already cooled down and is ready for the next heat dissipation circulation cycle.

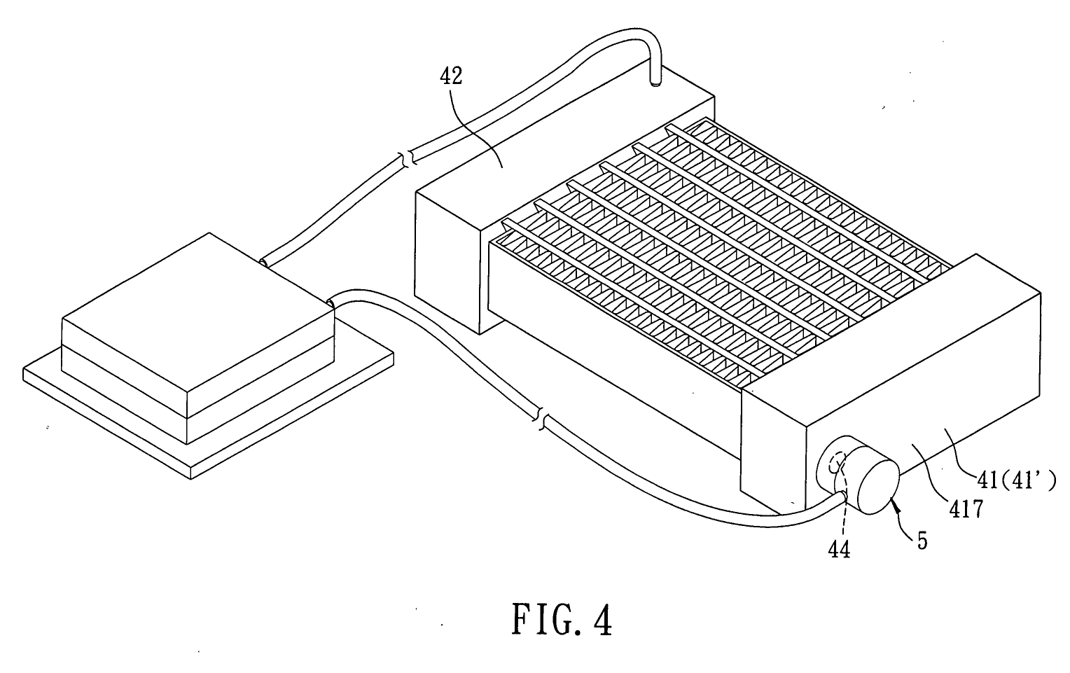

Referring to FIG. 4, the second preferred embodiment of this invention differs from the previous embodiment in that each of the first and second side tanks 41, 42 of the first preferred embodiment is columnar in shape, while each of the first and second side tanks 41, 42 of the second preferred embodiment is rectangular in shape. In this embodiment, the housing 41′ of the first side tank 41 has a pump-mounting wall 417 facing in the first direction, and the coolant outlet 44 of the first side tank 41 is formed on the pump-mounting wall 417.

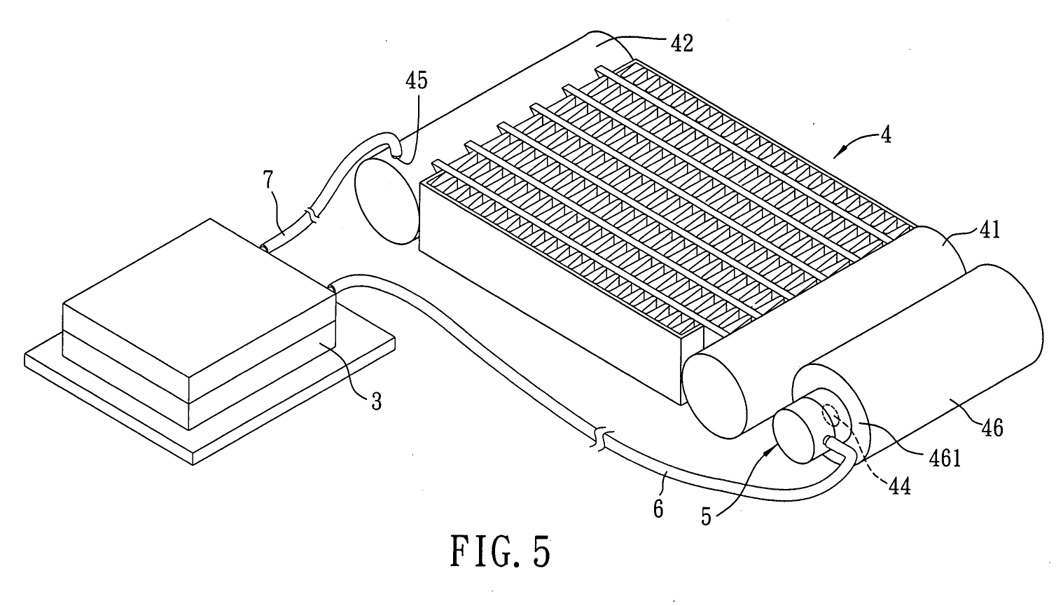

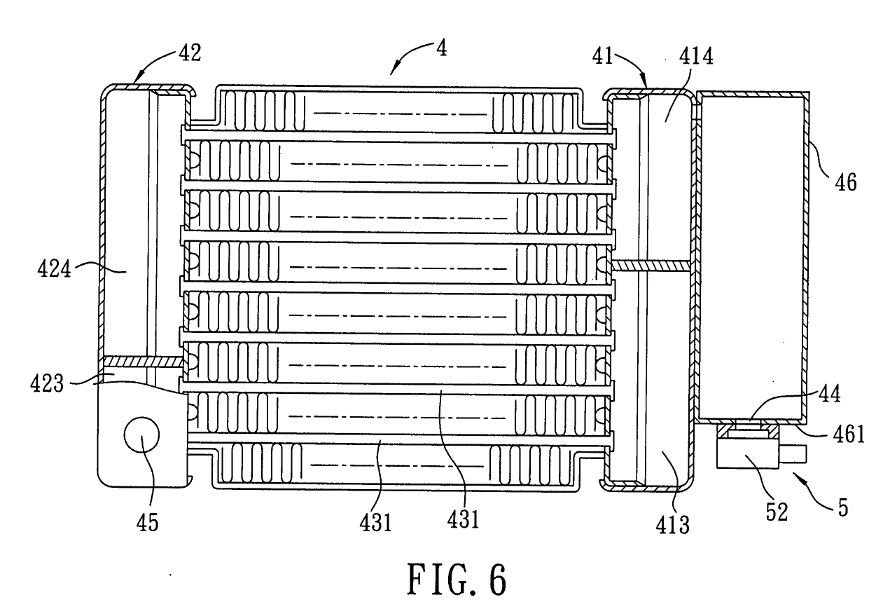

Referring to FIGS. 5 and 6, the third preferred embodiment of this invention differs from the first preferred embodiment in that the radiator 4 of this embodiment further includes a buffer tank 46 that is mounted on and that is in fluid communication with the second chamber 414 of the first side tank 41. The coolant outlet 44 is formed on a pump-mounting wall 461 of the buffer tank 46 which faces in the second direction. The pump 5 is mounted directly on the pump-mounting wall 461 of the buffer tank 46.

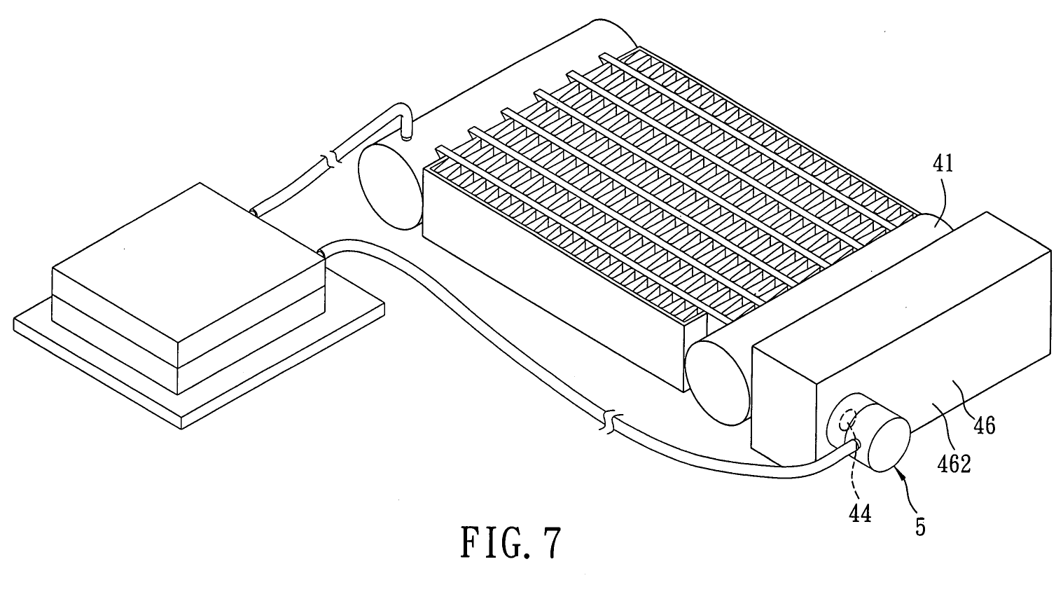

Referring to FIG. 7, the fourth preferred embodiment of this invention differs from the third preferred embodiment in that the buffer tank 46 of the third preferred embodiment is columnar in shape, and the pump-mounting wall 461 faces in the second direction, while the buffer tank 46 of the fourth preferred embodiment is rectangular in shape, and has a pump-mounting wall 462 facing in the first direction.

By mounting the pump 5 directly on the first side tank 41 or the buffer tank 46 of the heat dissipating device of this invention, the aforesaid drawbacks associated with the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A heat dissipating device adapted to be connected to a heat sink, comprising:
a radiator including first and second side tanks adapted to store a coolant therein, a fin structure disposed between and interconnecting said first and second side tanks, and a plurality of connecting conduits connected to said fin structure and interconnecting and in fluid communication with said first and second side tanks, said first side tank having a coolant outlet that is adapted to be connected to the heat sink, said second side tank having a coolant inlet that is adapted to be connected to the heat sink; and
a pump mounted directly on said first side tank so as to circulate the coolant through said first side tank, the heat sink, said second side tank, and said connecting conduits.

2. The heat dissipating device as claimed in claim 1, wherein said first and second side tanks are opposite to each other in a first direction, said first side tank having a housing that has a pump-mounting wall facing in a second direction transverse to said first direction, said coolant outlet of said first side tank being formed on said pump-mounting wall.

3. The heat dissipating device as claimed in claim 1, wherein said first and second side tanks are opposite to each other in a first direction, said first side tank having a housing that has a pump-mounting wall facing in said first direction, said coolant outlet of said first side tank being formed on said pump-mounting wall.

4. The heat dissipating device as claimed in claim 1, wherein said coolant outlet of said first side tank is provided with a cylindrical coupler, said pump having an inlet port that is connected to said coolant outlet of said first side tank through said cylindrical coupler.

5. A heat dissipating device adapted to be connected to a heat sink, comprising:
a radiator including first and second side tanks adapted to store a coolant therein, a fin structure disposed between and interconnecting said first and second side tanks, and a plurality of connecting conduits connected to said fin structure and interconnecting and in fluid communication with said first and second side tanks, said radiator further including a buffer tank that is mounted on and that is in fluid communication with said first side tank and that has a coolant outlet adapted to be connected to the heat sink, said second side tank having a coolant inlet that is adapted to be connected to the heat sink; and
a pump mounted directly on said buffer tank so as to circulate the coolant through said buffer tank, the heat sink, said second side tank, said connecting conduits, and said first side tank.

6. The heat dissipating device as claimed in claim 5, wherein said first and second side tanks are opposite to each other in a first direction, said first side tank having a first wall facing in said first direction, and a second wall transverse to said first wall, said buffer tank being mounted on said first wall of said first side tank, and having a housing that has a pump-mounting wall facing in a second direction transverse to said first direction, said coolant outlet of said buffer tank being formed on said pump-mounting wall.

7. The heat dissipating device as claimed in claim 5, wherein said first and second side tanks are opposite to each other in a first direction, said first side tank having a first wall facing in said first direction, said buffer tank being mounted on said first wall of said first side tank, and having a housing that has a pump-mounting wall facing in said first direction, said coolant outlet of said buffer tank being formed on said pump-mounting wall.

8. The heat dissipating device as claimed in claim 5, wherein said coolant outlet of said buffer tank is provided with a cylindrical coupler, said pump having an inlet port that is connected to said coolant outlet of said buffer tank through said cylindrical coupler.
